(19) United States
(12) Patent Application Publication
(10) Pub. No.: US 2008/0174235 A1
(43) Pub. Date: Jul. 24, 2008

(54) MASK USED TO FABRICATE ORGANIC LIGHT-EMITTING DIODE (OLED) DISPLAY DEVICE, METHOD OF FABRICATING OLED DISPLAY DEVICE USING THE MASK, OLED DISPLAY DEVICE FABRICATED USING THE MASK, AND METHOD OF FABRICATING THE MASK

(75) Inventors: Sun Hoe Kim, Suwon-si (KR); Sok Won Noh, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung SDI Co., Ltd., Suwon-si (KR)

(21) Appl. No.: 11/765,590

(22) Filed: Jun. 20, 2007

(30) Foreign Application Priority Data
Oct. 13, 2006 (KR) 2006-99838

(51) Int. Cl. H01J 1/62; C23C 16/44; B05D 5/06

(52) U.S. Cl. 313/504; 118/722; 427/164

(57) ABSTRACT

A mask used to fabricate an organic light-emitting diode (OLED) display device, the OLED display device including a plurality of pixel rows each including a plurality of pixel regions, the mask including a masking portion having formed therein a plurality of opening portions that form a patterned layer of material in the OLED display device during fabrication of the OLED display device; wherein each of the opening portions corresponds to a respective one of the pixel rows of the OLED display device, and includes a plurality of openings each corresponding to at least two of the pixel regions of the OLED display device in the respective pixel row.

### CROSS-REFERENCE TO RELATED APPLICATIONS

This application claims the benefit of Korean Patent Application No. 2006-99838 filed on Oct. 13, 2006, in the Korean Intellectual Property Office, the disclosure of which is incorporated herein by reference in its entirety.

### BACKGROUND OF THE INVENTION

1. Field of the Invention

Aspects of the invention relate to a mask used to fabricate an organic light-emitting diode (OLED) display device, a method of fabricating an OLED display device using the mask, an OLED display device fabricated using the mask, and a method of fabricating the mask. More particularly, a mask according to an aspect of the invention is fabricated to prevent distortion of openings of the mask while the mask is being used to fabricate an OLED display device by forming a plurality of opening portions in a masking portion, wherein each of the opening portions corresponds to a respective one of a plurality of pixel rows of the OLED display device, and includes a plurality of openings each corresponding to at least two pixel regions of the OLED display device in the respective pixel row. A distance between adjacent ones of the openings within each of the opening portions may be 90 to 170 μm.

2. Description of the Related Art

In general, an organic light-emitting diode (OLED) display device includes an intermediate layer including at least a light-emitting layer between opposing electrodes. The intermediate layer may include other layers in addition to the light-emitting layer, such as a hole injecting layer, a hole transporting layer, an electron injecting layer and an electron transporting layer. The layers of the intermediate layer are organic thin films made of organic materials.

In the process of manufacturing the OLED display device having the above constitution, a mask is indispensable for forming the organic thin films such as the hole injecting layer, the hole transporting layer, the light-emitting layer, the electron injecting layer and the electron transporting layer at proper positions on a substrate from evaporation material evaporated from a vapor evaporation apparatus. A mask having dot-shaped openings has typically been used for this purpose. However, such a mask has a disadvantage in that the thin films cannot be formed uniformly in regions in which the incident angle of the evaporation material evaporated from the vapor evaporation source becomes small due to an increase in the size of the substrate in order to provide an OLED display device having a large screen. Accordingly, a mask having stripe-shaped openings, which makes it easy to control the aperture ratio of the OLED display device and is relatively simple to manufacture, has been used instead of the mask having the dot-shaped openings.

A method of forming thin films using a mask having stripe-shaped openings according to the related art will now be described.

FIG. 1 is a cross-sectional view of a vapor evaporation apparatus for forming thin films on a substrate according to the related art. FIG. 2 is a plan view of a mask according to the related art shown in FIG. 1.

Referring to FIGS. 1 and 2, in a chamber (not shown) there is placed a substrate 100 for forming an organic film, a mask 110 positioned on the front face of the substrate 100 and at least one vapor deposition source 130 separated from the mask 110 by a predetermined distance.

In order to form thin films on the substrate 100, the vapor deposition source 130, which holds a deposition material, is first heated to evaporate the deposition material. The deposition material evaporated from the vapor deposition source 130 is deposited in pixel regions of the substrate 100 through opening portions 111 of a pattern formed on the mask 110. The mask 110 includes a first opening portion 111R having a stripe shape in a region of the mask 110 corresponding to a pixel regions R in a pixel row in which a red light-emitting layer is to be formed, a second opening portion 111G having a stripe shape in a region of the mask 110 corresponding to a pixel regions G in a pixel row in which a green light-emitting layer is to be formed, and a third opening portion 111B having a stripe shape in a region of the mask 110 corresponding to a pixel regions B in a pixel row in which a blue light-emitting layer is to be formed.

Accordingly, thin films 101 having a pattern corresponding to the stripe shape of the opening portions 111 are formed in the pixel regions R, G and B of the substrate 100.

However, the mask having the opening portions having the stripe shape suffers from distortion due to drooping of the sides of the opening portions in a central region of the mask caused by an external tensile force applied to the mask and the weight of the mask itself. This causes the distance from one side of the opening portion to the other side of the opening portion, i.e., the width of the opening portion, to change along the length of the opening portion. This makes it impossible to deposit thin films having a uniform pattern on the substrate.

### SUMMARY OF THE INVENTION

According to aspects of the invention, there are provided a mask used to fabricate an organic light-emitting diode (OLED) display device, a method of fabricating an OLED display device using the mask, an OLED display device fabricated using the mask, and a method of fabricating the mask.

According to an aspect of the invention, a mask is fabricated to prevent distortion of openings of the mask while the mask is being used to fabricate an OLED display device by forming a plurality of opening portions in a masking portion, wherein each of the opening portions corresponds to a respective one of a plurality of pixel rows of the OLED display device, and includes a plurality of openings each corresponding to at least two pixel regions of the OLED display device in the respective pixel row. A distance between adjacent ones of the openings within each of the opening portions may be 90 to 170 μm.

According to an aspect of the invention, there is provided a mask used to fabricate an organic light-emitting diode (OLED) display device, the OLED display device including a plurality of pixel rows each including a plurality of pixel regions, the mask including a masking portion having formed therein a plurality of opening portions that form a patterned layer of material in the OLED display device during fabrication of the OLED display device; wherein each of the opening portions corresponds to a respective one of the pixel rows of the OLED display device, and includes a plurality of openings each corresponding to at least two of the pixel regions of the OLED display device in the respective pixel row.

According to an aspect of the invention, there is provided a method of fabricating an organic light-emitting diode (OLED) display device using a mask, the OLED display device including a plurality of pixel rows each including a plurality of pixel regions, the method including disposing a mask to face a partially fabricated OLED display device, the mask including a masking portion having formed therein a plurality of opening portions, wherein each of the opening portions corresponds to a respective one of the pixel rows of the OLED display device, and includes a plurality of openings each corresponding to at least two of the pixel regions of the OLED display device in the respective pixel row; and forming a patterned layer of material on the partially fabricated OLED display device through the openings of the mask.

According to an aspect of the invention, there is provided an organic light-emitting diode (OLED) display device fabricated using a mask, the OLED display device including a plurality of pixel rows each including a plurality of pixel regions; and a patterned layer of material including a plurality of line portions; wherein each of the line portions of the patterned layer of material corresponds to a respective one of the pixel rows, and includes a plurality of stripe portions each corresponding to at least two of the pixel regions in the respective pixel row; wherein the mask includes a masking portion having formed therein a plurality of opening portions that form the patterned layer of material during fabrication of the OLED display device; wherein each of the opening portions of the mask corresponds to a respective one of the pixel rows of the OLED display device, and includes a plurality of openings each corresponding to at least two of the pixel regions of the OLED display device in the respective pixel row; and wherein the stripe portions of the OLED display device are formed through the openings of the mask during the fabrication of the OLED display device.

According to an aspect of the invention, there is provided a method of fabricating a mask used to fabricate an organic light-emitting diode (OLED) display device, the OLED display device including a plurality of pixel rows each including a plurality of pixel regions, the method including forming a masking portion; and forming a plurality of opening portions in the masking portion; wherein the opening portions form a patterned layer of material in the OLED display device during fabrication of the OLED display device; and wherein each of the opening portions corresponds to a respective one of the pixel rows of the OLED display device, and includes a plurality of openings each corresponding to at least two of the pixel regions of the OLED display device in the respective pixel row.

Additional aspects and/or advantages of the invention will be set forth in part in the description which follows and, in part, will be obvious from the description, or may be learned by practice of the invention.

### BRIEF DESCRIPTION OF THE DRAWINGS

The above and/or other aspects and advantages of the invention will become apparent and more readily appreciated from the following description of embodiments of the invention, taken in conjunction with the accompanying drawings of which:

FIG. 1 is a cross-sectional view of a vapor evaporation apparatus for forming thin films on a substrate according to the related art;

FIG. 2 is a plan view a mask according to the related art shown in FIG. 1;

FIG. 3 is a cross-sectional view of a vapor evaporation apparatus for forming thin films on a substrate according to an aspect of the invention;

FIG. 4 is a plan view of a mask according to an aspect of the invention shown in FIG. 3;

FIG. 5 is a perspective view of an organic light-emitting diode (OLED) display device according to an aspect of the invention;

FIG. 6 is a cross-sectional view of the OLED display device of FIG. 5 according to an aspect of the invention taken along the line VI-VI′ in FIG. 5;

FIG. 7 is a cross-sectional view of the OLED display device of FIG. 5 according to an aspect of the invention taken along the line VII-VII′ in FIG. 5; and

FIG. 8 is a cross-sectional view of the OLED display device of FIG. 5 according to an aspect of the invention taken along the line VIII-VIII′ in FIG. 5.

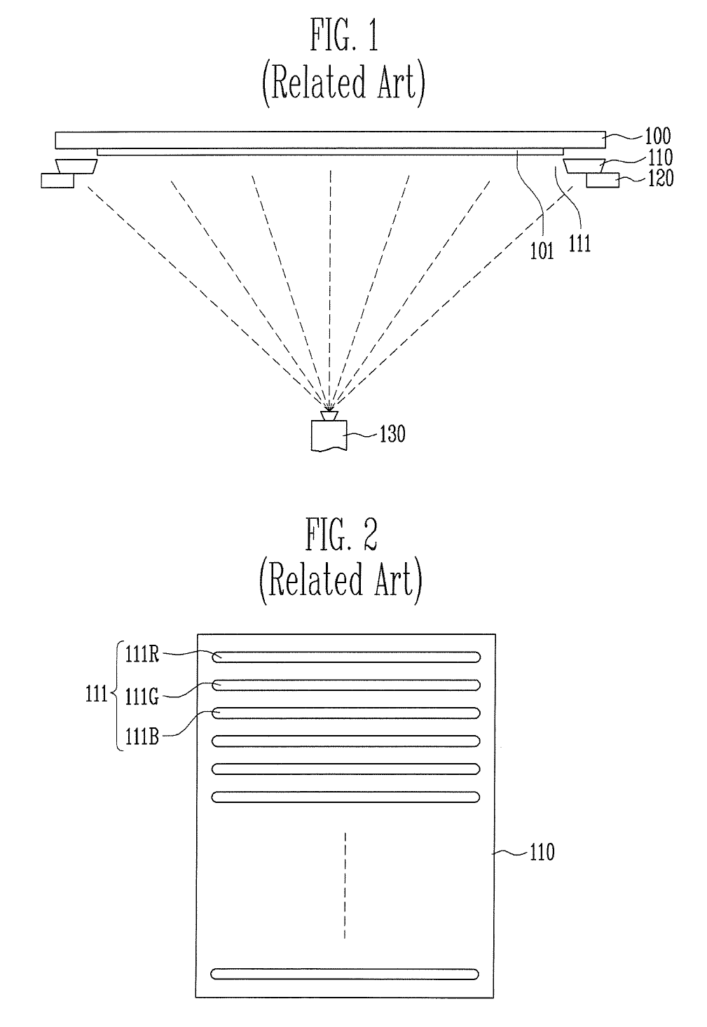

### DETAILED DESCRIPTION OF THE EMBODIMENTS

Reference will now be made in detail to embodiments of the invention, examples of which are illustrated in the accompanying drawings, wherein like reference numerals refer to like elements throughout. The embodiments are described below in order to explain the invention by referring to the figures.

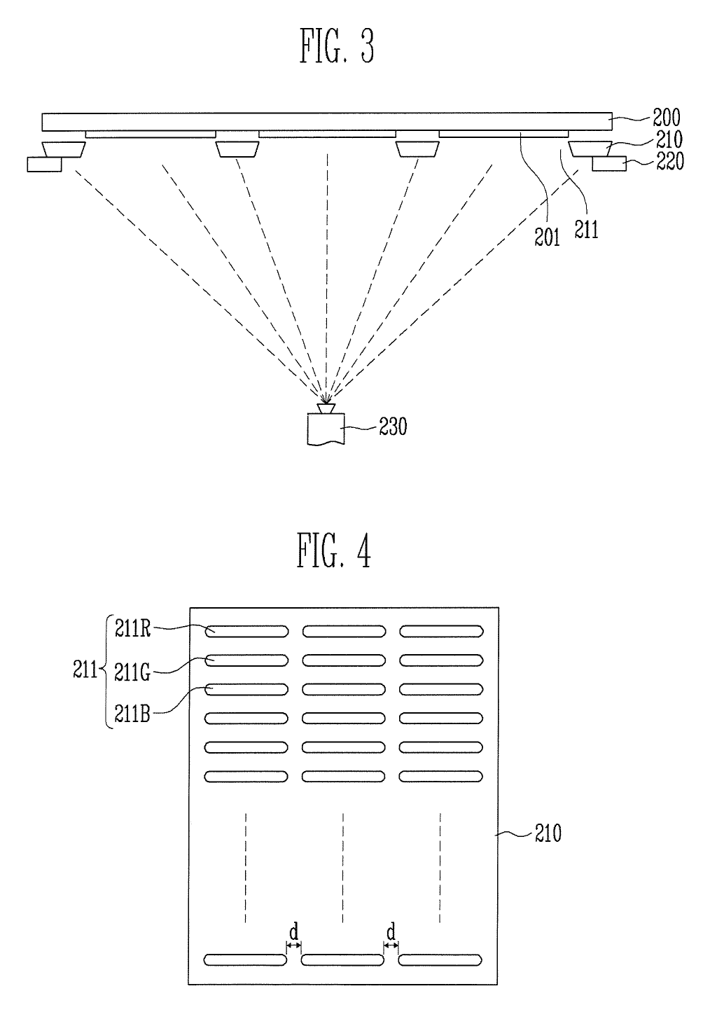

FIG. 3 is a cross-sectional view of a vapor evaporation apparatus for forming thin films on a substrate of an organic light-emitting diode (OLED) display device according to an aspect of the invention. FIG. 4 is a plan view of a mask according to an aspect of the invention shown in FIG. 3.

Referring to FIGS. 3 and 4, a mask 210 according to an aspect of the invention, which is for depositing thin films 201 including at least red, green and blue light-emitting layers in a plurality of pixel regions R, G and B arranged in a plurality of pixel rows, includes a plurality of opening portions 211 in a portion of the mask 210 corresponding to the plurality of pixel regions, wherein each of the opening portions 211 includes a plurality of openings that are separated from each other by a distance d of 90 to 170 μm.

A vapor deposition source 230 is positioned in the lower part of a chamber (not shown). The vapor deposition source 230 holds a deposition material and includes a heat source for heating the deposition material so that the deposition material may be deposited on a substrate 200. The vapor deposition source 230 is moved relative to the substrate 200 by a moving device (not shown) mounted in the chamber as necessary to deposit the deposition material on the entire surface of the substrate 200. Also, the vapor deposition source 230 may be configured as a plurality of vapor deposition sources in order to form the deposition material on the entire surface of substrate 200 when the substrate 200 is a large-screen substrate.

Also, a substrate supporting device (not shown) for supporting the substrate 200 in an upper part of the chamber to oppose the vapor deposition source 230 positioned in the lower part of the chamber is provided in the upper part of the chamber. The mask 210, which determines a pattern of thin films that will be formed on the substrate 200, is mounted in a mask frame 220 that holds the mask 210 against a front surface of the substrate 200. An external tension is typically applied to the mask 210 by the mask frame 220.

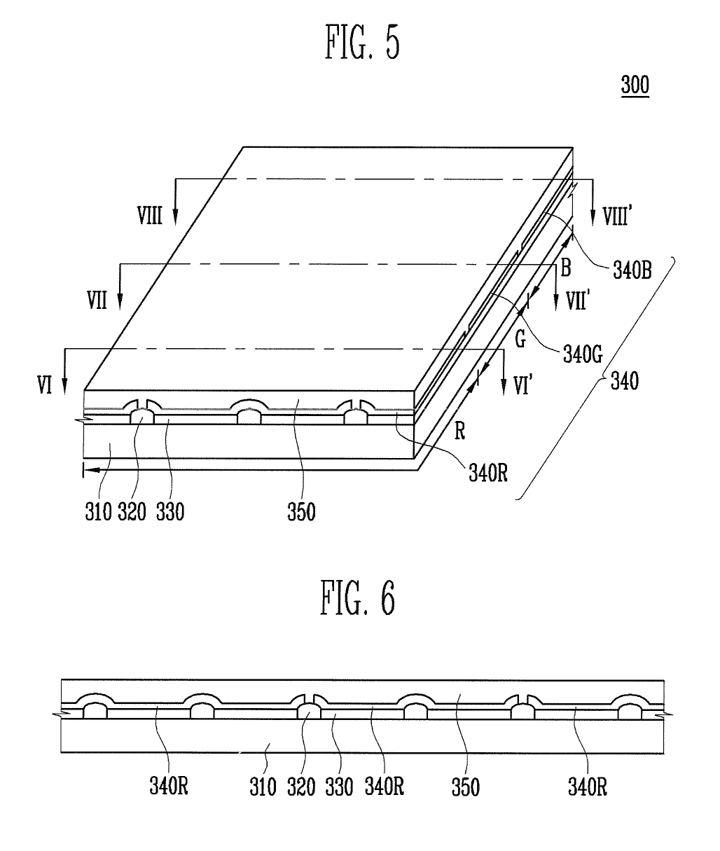

A plurality of pixel regions arranged in a plurality of pixel rows are formed on the substrate 200. The pixel regions are defined by a plurality of first electrodes formed on the substrate extending in the same direction as the pixel rows, and a pixel defining layer (PDL) (not shown in FIGS. 3 and 4, but shown in FIGS. 5 to 8 which are discussed below) formed on the substrate and including opening portions for exposing portions of the first electrodes. In other words, the pixel regions are regions of the first electrodes formed on the substrate 200 that are exposed by the opening portions of the pixel defining layer. Each of the pixel rows corresponds to a respective one of the first electrodes.

The mask 210 includes a first opening portion 211R including a plurality of striped-shaped openings in a region of the mask 210 corresponding to pixel regions R in a pixel row in which a red light-emitting layer is to be formed, a second opening portion 211G including a plurality of stripe-shaped openings in a region of the mask 210 corresponding to pixel regions G in a pixel row in which a green light-emitting layer is to be formed, and a third opening portion 211B including a plurality of stripe-shaped openings in a region of the mask 210 corresponding to pixel regions B in a pixel row in which a blue light-emitting layer is to be formed. Each of the striped-shaped openings of the opening portions 211 corresponds to at least two pixel regions in one pixel row. Accordingly, the light-emitting layers formed in the pixel regions will be formed as a plurality of line portions each corresponding to a respective one of the pixel rows, and each including a plurality of stripe portions each corresponding to at least two of the pixel regions in the respective one of the pixel rows.

Adjacent ones of the plurality of openings within each of the opening portions 211 are separated from each other by a distance d of 90 to 170 μm to prevent the distortion of the mask 210 that occurs when a length of an opening in the mask 210 exceeds a certain length that depends on the thickness of the mask 210, the material of which the mask 210 is made, and an external tension that is applied to the mask 210 by the mask frame 220. For example, the first opening portion 211R is formed to correspond to a first one of a plurality of first electrodes formed on the substrate 200 extending in one direction, and includes a plurality of first openings, adjacent ones of which are separated from each other by a distance d of 90 to 170 μm. The second opening portion 211G is formed to correspond to a second one of the first electrodes adjacent to the first one of the first electrodes corresponding to the first opening portion 211R, and includes a plurality of second openings, adjacent ones of which are separated from each other by a distance d of 90 to 170 μm. The third opening portion 211B is formed to correspond to a third one of the first electrodes adjacent to the second one of the first electrodes corresponding to the second opening portion 211G, and includes a plurality of third openings, adjacent ones of which are separated from each other by a distance d of 90 to 170 μm.

One example of a 40-inch substrate has pixel regions measuring 462×462 μm. Each of these pixel regions is divided into red, green, and blue sub-pixel regions each measuring 154×462 μm. In a 40-inch substrate formed using a mask having dot-shaped openings according to the related art, one stripe-shaped opening is formed in each of the 154×462 μm sub-pixel regions, so that a total of three stripe-shaped openings are formed in each of the 462×462 μm pixel regions. In contrast, according to an aspect of the invention, a plurality of stripe-shaped openings are formed in the direction of the longer dimension (462 μm) of the 154×462 μm sub-pixel regions so that each of the striped-shaped openings extends through a plurality of the 154×462 μm sub-pixel regions. Adjacent ones of the stripe-shaped openings are separated from each other by a distance d of 90 to 170 μm. For example, each of the first striped-shaped openings of the first opening portion 211R shown in FIG. 4 extend through a plurality of the 154×462 μm red sub-pixel regions; each of the second striped-shaped openings of the second opening portion 211G shown in FIG. 4 extend through a plurality of the 154×462 μm green sub-pixel regions; and each of the third striped-shaped openings of the third opening portion 211B shown in FIG. 4 extend through a plurality of the 154×462 μm blue sub-pixel regions.

If the distance d between adjacent openings in one opening portion 211 is less than 90 μm, the thin films 201 cannot be formed uniformly on the substrate 200 due to interference caused by the pattern of the mask 210, and if the distance d between adjacent openings in one opening portion 211 is more than 170 μm, the ability of the mask 210 to maintain the shape of the openings in the opening portions 211 deteriorates.

The first opening portion 211R, the second opening portion 211G and the third opening portion 211B are adjacent to each other, and may be formed to extend in the horizontal direction as shown in FIG. 4, or in the vertical direction (not shown in the drawings.

As described above, there are a plurality of opening portions 211 each including a plurality of openings forming the light-emitting layers in the pixel regions of the substrate 200, wherein distortion of the mask 210 is prevented by separating adjacent openings in one opening portion from each another by a distance d of 90 to 170 μm. Accordingly, uniformity of the thin films 201 formed on the substrate 200 can be improved.

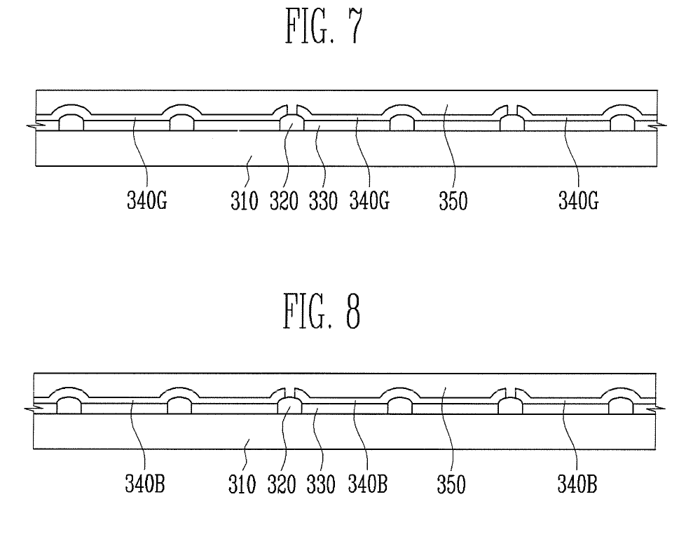

FIG. 5 is a perspective view of an organic light-emitting diode (OLED) display device according to an aspect of the invention. FIG. 6 is a cross-sectional view of the OLED display device of FIG. 5 according to an aspect of the invention taken along the line VI-VI′ in FIG. 5. FIG. 7 is a cross-sectional view of the OLED display device of FIG. 5 according to an aspect of the invention taken along the line VII-VII′ in FIG. 5. FIG. 8 is a cross-sectional view of the OLED display device of FIG. 5 according to an aspect of the invention device taken along the line VIII-VIII′ in FIG. 5.

Referring to FIGS. 5 to 8, an OLED display device 300 according to an aspect of the invention includes first electrodes 330 and a second electrode 350 opposing each other and supported by a substrate 310, and light-emitting layers 340 provided between the first electrodes 330 and the second electrode 350, wherein the light-emitting layers 340 are formed as a plurality of line portions each corresponding to a respective one of a plurality of pixel rows, and including a plurality of stripe portions each corresponding to at least two pixel regions in the respective one of the pixel rows. Adjacent ones of the stripe portions in each of the line portions are separated from each other by a distance of 90 to 170 μm.

The substrate 310 may be made of an insulating material such as glass, plastic, silicon or synthetic resin. Preferably, the substrate 310 is a transparent substrate such as a glass substrate. In general, thin film transistors are formed on the substrate 310. For convenience, a detailed description of the thin film transistors will be omitted because this will already be known to one of ordinary skill in the art.

The first electrodes 330 are formed in a line shape on the substrate 310 by a patterning process. The first electrodes 330 may be made of a transparent material or a reflective material. When the first electrodes 330 are made of a transparent material, they may be formed of a transparent film of ITO, IZO, ZnO or In₂O₃. When the first electrodes 330 are made of a reflective material, they may be formed of a reflective film including one or more of Ag, Mg, Al, Pt, Pd, Au, Ni, Nd, Ir, Cr and compounds thereof with a transparent film of ITO, IZO, ZnO or In₂O₃ thereon. A pixel defining layer (PDL) 320, which is formed on the substrate 310, has opening portions that partially expose the first electrodes 330 to define pixel regions.

A red light-emitting layer 340R, a green light-emitting layer 340G and a blue light-emitting layer 340B are formed in a stripe shape in the pixel regions by a patterning process. The red light-emitting layer 340R includes a plurality of stripe portions separated from each other by a distance of 90 to 170 μm, the green light-emitting layer 340G includes a plurality of stripe portions separated from each other by a distance of 90 to 170 μm and the blue light-emitting layer 340B includes a plurality of stripe portions separated from each other by a distance of 90 to 170 μm. The red light-emitting layer 340R, the green light-emitting layer 340G and the blue light-emitting layer 340B that are arranged in sequence form a color triad of red, green and blue, and this sequence is repeated throughout the OLED display device, thereby implementing a full-color OLED display device.

The second electrode 350 is formed as a continuous layer over the entire surface of the OLED display device. The second electrode 350 may be made of a transparent material or a reflective material. When the second electrode 350 is made of a transparent material, it is used as a cathode electrode, and may be formed of a transparent film of a metal having a small work function, for example, a transparent film including one or more of Li, Ca, LiF/Ca, LiF/AI, Al, Ag, Mg, and compounds thereof with a transparent film of ITO, IZO, ZnO or In₂O₃ thereon. When the second electrode 350 is made of a reflective material, it may be formed of a reflective film including one or more of Li, Ca, LiF/Ca, LiF/AI, Al, Ag, Mg and compounds thereof. Alternatively, a plurality of second electrodes 350 may be formed in a line shape on the pixel defining layer 320, the red light-emitting layer 340R, the green light-emitting layer 340G and the blue light-emitting layer 340B by a patterning process so that the second electrodes 350 intersect the first electrodes 330.

As described above, according to an aspect of the invention, distortion of the mask is prevented by forming a plurality of opening portions each corresponding to a respective one of a plurality of pixel rows and each including a plurality of openings each corresponding to at least two pixel regions in the respective one of the plurality of pixel rows, wherein adjacent ones of the openings in each one of the opening portions are separated from each other by a distance of 90 to 170 μm. Accordingly, when a large-sized mother glass is used for mass production of an organic light-emitting diode (OLED) display device or for production of an OLED display device having a large screen size, distortion of the mask caused by the large size of the mask necessitated by the large-sized mother glass is reduced. Therefore, the thin film layers can uniformly be formed on the substrate.

Although several embodiments of the invention have been shown and described, it would be appreciated by those skilled in the art that changes may be made in these embodiments without departing from the principles and spirit of the invention, the scope is defined in the claims and their equivalents.

What is claimed is:

1. A mask used to fabricate an organic light-emitting diode (OLED) display device, the OLED display device comprising a plurality of pixel rows each comprising a plurality of pixel regions, the mask comprising:
a masking portion having formed therein a plurality of opening portions that form a patterned layer of material in the OLED display device during fabrication of the OLED display device;
wherein each of the opening portions corresponds to a respective one of the pixel rows of the OLED display device, and comprises a plurality of openings each corresponding to at least two of the pixel regions of the OLED display device in the respective pixel row.

2. The mask of claim 1, wherein a distance between adjacent ones of the openings within each of the opening portions is 90 to 170 μm.

3. The mask of claim 1, wherein the OLED display device further comprises a pixel defining layer that defines the pixel regions of the OLED display device; and
wherein adjacent ones of the openings within each of the opening portions are separated from each another by respective portions of the masking portion respectively corresponding to portions of the pixel defining layer of the OLED display device.

4. The mask of claim 1, wherein a length of each of the opening portions is substantially equal to a length of each of the pixels rows of the OLED display device.

5. The mask of claim 1, wherein a length of each of the openings within each of the opening portions is large enough to prevent distortion of the openings while the mask is being used to form the patterned layer of material in the OLED display device.

6. The mask of claim 1, wherein a length of each of the openings within each of the opening portions is greater than a length that results in distortion of the openings while the mask is being used to form the patterned layer of material in the OLED display device.

7. The mask of claim 6, wherein the length that results in the distortion of the openings while the mask is being used to form the patterned layer of material in the OLED display device is less than a length of each of the pixel rows of the OLED display device, and is greater than a total width of two adjacent ones of the pixel regions of the OLED display device within each of the pixel rows.

8. The mask of claim 1, wherein a distance between adjacent ones of the openings within each of the opening portions is small enough to prevent distortion of the openings while the mask is being used to form the patterned layer of material in the OLED display device.

9. The mask of claim 1, wherein a distance between adjacent ones of the openings within each of the opening portions is large enough to prevent the patterned layer of material in the OLED display device from being formed nonuniformly while the mask is being used to form the patterned layer of material in the OLED display device.

10. The mask of claim 1, wherein the pixel rows of the OLED display device comprise:
a plurality of red-emitting pixel rows each comprising a plurality of red-emitting pixel regions,
a plurality of green-emitting pixel rows each comprising a plurality of green-emitting pixel regions, and
a plurality of blue-emitting pixel rows each comprising a plurality of blue-emitting pixel regions; and
wherein the opening portions comprise:
a first plurality of opening portions respectively corresponding to the red-emitting pixel rows of the OLED display device,
a second plurality of opening portions respectively corresponding to the green-emitting pixel rows of the OLED display device, and
a third plurality of opening portions respectively corresponding to the blue-emitting pixel rows of the OLED display device.

11. A method of fabricating an organic light-emitting diode (OLED) display device using a mask, the OLED display device comprising a plurality of pixel rows each comprising a plurality of pixel regions, the method comprising:
disposing a mask to face a partially fabricated OLED display device, the mask comprising a masking portion having formed therein a plurality of opening portions, wherein each of the opening portions corresponds to a respective one of the pixel rows of the OLED display device, and comprises a plurality of openings each corresponding to at least two of the pixel regions of the OLED display device in the respective pixel row; and
forming a patterned layer of material on the partially fabricated OLED display device through the openings of the mask.

12. The method of claim 11, wherein a distance between adjacent ones of the openings within each of the opening portions is 90 to 170 μm.

13. The method of claim 11, wherein the OLED display device further comprises a pixel defining layer that defines the pixel regions of the OLED display device; and
wherein adjacent ones of the openings within each of the opening portions are separated from each another by respective portions of the masking portion respectively corresponding to portions of the pixel defining layer of the OLED display device.

14. The method of claim 11, wherein a length of each of the opening portions is substantially equal to a length of each of the pixels rows of the OLED display device.

15. The method of claim 11, wherein a length of each of the openings within each of the opening portions is large enough to prevent distortion of the openings while the patterned layer of material is being formed on the partially fabricated OLED display device through the openings of the mask.

16. The method of claim 11, wherein a length of each of the openings within each of the opening portions is greater than a length that results in distortion of the openings while the patterned layer of material is being formed on the partially fabricated OLED display device through the openings of the mask.

17. The method of claim 16, wherein the length that results in the distortion of the openings while the patterned layer of material is being formed on the partially fabricated OLED display device through the openings of the mask is less than a length of each of the pixel rows of the OLED display device, and is greater than a total width of two adjacent ones of the pixel regions of the OLED display device within each of the pixel rows.

18. The method of claim 11, wherein a distance between adjacent ones of the openings within each of the opening portions is small enough to prevent distortion of the openings while the patterned layer of material is being formed on the partially fabricated OLED display device through the openings of the mask.

19. The method of claim 11, wherein a distance between adjacent ones of the openings within each of the opening portions is large enough to prevent the patterned layer of material from being formed nonuniformly while the patterned layer of material is being formed on the partially fabricated OLED display device through the openings of the mask.

20. The method of claim 11, wherein the pixel rows of the OLED display device comprise
a plurality of red-emitting pixel rows each comprising a plurality of red-emitting pixel regions,
a plurality of green-emitting pixel rows each comprising a plurality of green-emitting pixel regions, and
a plurality of blue-emitting pixel rows each comprising a plurality of blue-emitting pixel regions;
wherein the opening portions comprise:
a first plurality of opening portions respectively corresponding to the red-emitting pixel rows of the OLED display device,
a second plurality of opening portions respectively corresponding to the green-emitting pixel rows of the OLED display device, and
a third plurality of opening portions respectively corresponding to the blue-emitting pixel rows of the OLED display device; and
wherein the forming of the patterned layer of material comprises:
forming a patterned layer of red-emitting material on the partially fabricated OLED display device through the openings of the first plurality of opening portions,
forming a patterned layer of green-emitting material on the partially fabricated OLED display device through the openings of the second plurality of opening portions, and
forming a patterned layer of blue-emitting material on the partially fabricated OLED display device through the openings of the third plurality of opening portions.

21. An organic light-emitting diode (OLED) display device fabricated using a mask, the OLED display device comprising:
a plurality of pixel rows each comprising a plurality of pixel regions; and
a patterned layer of material comprising a plurality of line portions;
wherein each of the line portions of the patterned layer of material corresponds to a respective one of the pixel rows, and comprises a plurality of stripe portions each corresponding to at least two of the pixel regions in the respective pixel row;
wherein the mask comprises a masking portion having formed therein a plurality of opening portions that form the patterned layer of material during fabrication of the OLED display device;
wherein each of the opening portions of the mask corresponds to a respective one of the pixel rows of the OLED display device, and comprises a plurality of openings each corresponding to at least two of the pixel regions of the OLED display device in the respective pixel row; and
wherein the stripe portions of the OLED display device are formed through the openings of the mask during the fabrication of the OLED display device.

22. The OLED display device of claim 21, wherein a distance between adjacent ones of the openings of the mask within each of the opening portions of the mask is 90 to 170 μm; and
wherein a distance between adjacent ones of the stripe portions of the OLED display device within each of the line portions of the OLED display device is 90 to 170 μm.

23. The OLED display device of claim 21, further comprising a pixel defining layer that defines the pixel regions of the OLED display device;
wherein adjacent ones of the openings of the mask within each of the opening portions of the mask are separated from each another by respective portions of the masking portion of the mask respectively corresponding to portions of the pixel defining layer of the OLED display device; and
wherein adjacent ones of the stripe portions of the OLED display device within each of the line portions of the OLED display device are separated from each other by respective gaps respectively corresponding to the portions of the pixel defining layer of the OLED display device.

24. The OLED display device of claim 21, wherein a length of each of the opening portions of the mask is substantially equal to a length of each of the pixels rows of the OLED display device and a length of each of the line portions of the OLED display device.

25. The OLED display device of claim 21, wherein a length of each of the openings of the mask within each of the opening portions of the mask is large enough to prevent distortion of the openings of the mask while the stripe portions of the OLED display device are being formed through the openings of the mask.

26. The OLED display device of claim 21, wherein a length of each of the openings of the mask within each of the opening portions of the mask is greater than a length that results in distortion of the openings of the mask while the stripe portions of the OLED display device are being formed through the openings of the mask.

27. The OLED display device of claim 26, wherein the length that results in the distortion of the openings of the mask while the stripe portions of the OLED display device are being formed through the openings of the mask is less than a length of each of the pixel rows of the OLED display device and a length of each of the line portions of the OLED display device, and is greater than a total width of two adjacent ones of the pixel regions of the OLED display device within each of the pixel rows and a total length of two adjacent ones of the stripe portions of the OLED display device within each of the line portions of the OLED display device.

28. The OLED display device of claim 21, wherein a distance between adjacent ones of the openings of the mask within each of the opening portions of the mask is small enough to prevent distortion of the openings of the mask while the stripe portions of the OLED display device are being formed through the openings of the mask.

29. The OLED display device of claim 21, wherein a distance between adjacent ones of the openings of the mask within each of the opening portions of the mask is large enough to prevent the stripe portions of the OLED display device from being formed nonuniformly while the stripe portions of the OLED display device are being formed through the openings of the mask.

30. The OLED display device of claim 21, wherein the pixel rows of the OLED display device comprise:
a plurality of red-emitting pixel rows each comprising a plurality of red-emitting pixel regions,
a plurality of green-emitting pixel rows each comprising a plurality of green-emitting pixel regions, and
a plurality of blue-emitting pixel rows each comprising a plurality of blue-emitting pixel regions;
wherein the opening portions of the mask comprise:
a first plurality of opening portions respectively corresponding to the red-emitting pixel rows of the OLED display device,
a second plurality of opening portions respectively corresponding to the green-emitting pixel rows of the OLED display device, and
a third plurality of opening portions respectively corresponding to the blue-emitting pixel rows of the OLED display device; and
wherein the line portions of the OLED display device comprise:
a plurality of red-emitting line portions respectively corresponding to the red-emitting pixel rows of the OLED display device,
a plurality of green-emitting line portions respectively corresponding to the green-emitting pixel rows of the OLED display device, and
a plurality of blue-emitting line portions respectively corresponding to the blue-emitting pixel rows of the OLED display device.

31. A method of fabricating a mask used to fabricate an organic light-emitting diode (OLED) display device, the OLED display device comprising a plurality of pixel rows each comprising a plurality of pixel regions, the method comprising:
forming a masking portion; and
forming a plurality of opening portions in the masking portion;
wherein the opening portions form a patterned layer of material in the OLED display device during fabrication of the OLED display device; and
wherein each of the opening portions corresponds to a respective one of the pixel rows of the OLED display device, and comprises a plurality of openings each corresponding to at least two of the pixel regions of the OLED display device in the respective pixel row.

32. The method of claim 31, wherein a distance between adjacent ones of the openings within each of the opening portions is 90 to 170 μm.

33. The method of claim 31, wherein the OLED display device further comprises a pixel defining layer that defines the pixel regions of the OLED display device; and
wherein adjacent ones of the openings within each of the opening portions are separated from each another by respective portions of the masking portion respectively corresponding to portions of the pixel defining layer of the OLED display device.

34. The method of claim 31, wherein a length of each of the opening portions is substantially equal to a length of each of the pixels rows of the OLED display device.

35. The method of claim 31, wherein a length of each of the openings within each of the opening portions is large enough to prevent distortion of the openings while the mask is being used to form the patterned layer of material in the OLED display device.

36. The method of claim 31, wherein a length of each of the openings within each of the opening portions is greater than a length that results in distortion of the openings while the mask is being used to form the patterned layer of material in the OLED display device.

37. The method of claim 36, wherein the length that results in the distortion of the openings while the mask is being used to form the patterned layer of material in the OLED display device is less than a length of each of the pixel rows of the OLED display device, and is greater than a total width of two adjacent ones of the pixel regions of the OLED display device within each of the pixel rows.

38. The method of claim 31, wherein a distance between adjacent ones of the openings within each of the opening portions is small enough to prevent distortion of the openings while the mask is being used to form the patterned layer of material in the OLED display device.

39. The method of claim 31, wherein a distance between adjacent ones of the openings within each of the opening portions is large enough to prevent the patterned layer of material in the OLED display device from being formed nonuniformly while the mask is being used to form the patterned layer of material in the OLED display device.

40. The method of claim 31, wherein the pixel rows of the OLED display device comprise:
a plurality of red-emitting pixel rows each comprising a plurality of red-emitting pixel regions,
a plurality of green-emitting pixel rows each comprising a plurality of green-emitting pixel regions, and
a plurality of blue-emitting pixel rows each comprising a plurality of blue-emitting pixel regions; and
wherein the opening portions comprise:
a first plurality of opening portions respectively corresponding to the red-emitting pixel rows of the OLED display device,
a second plurality of opening portions respectively corresponding to the green-emitting pixel rows of the OLED display device, and
a third plurality of opening portions respectively corresponding to the blue-emitting pixel rows of the OLED display device.
